(19) United States
(12) Patent Application Publication
(10) Pub. No.: US 2006/0006765 A1
(43) Pub. Date: Jan. 12, 2006

(54) Apparatus and method to transmit and receive acoustic wave energy

(76) Inventor: Jongtae Yuk, Redmond, WA (US)

Correspondence Address: BLACK LOWE & GRAHAM, PLLC, 701 FIFTH AVENUE, SUITE 4800, SEATTLE, WA, 98104, US

(21) Appl. No.: 10/888,735

(22) Filed: Jul. 9, 2004

(51) Int. Cl. H01L 41/04

(52) U.S. Cl. 310/334

(57) ABSTRACT

A transducer device including a housing that encloses a three-layer piezoelectric crystal assembly in contact with a backing block to produce more finely resolved electric and acoustic pulses. The three-layer assembly includes a piezoelectric crystal flanked by a front and back matching layer with a backing block in contact with the back matching layer. In concert with the backing block, the front and back matching layers cooperatively interact to produce more highly resolved acoustic and electrical pulses than by transducers equipped with two-layer crystal assemblies.

### FIELD OF THE INVENTION

This invention relates generally to acoustic transducers.

### BACKGROUND OF THE INVENTION

Acoustic transducers (audible or ultrasound) include a two-layer piezoelectric crystal assembly coupled to a backing block. The backing block is generally made of tungsten powder and rubber in an epoxy resin and serves to dampen the vibrating two-layer piezoelectric crystal assembly when the crystal is no longer electro-stimulated by voltage pulses or mechanically stimulated by received acoustic pulses.

Backing blocks are used to mechanically dampen vibrations of the crystal assembly and to shorten ultrasonic pulses emitted by the crystal assembly. Accordingly, the backing block is desirably formed from an acoustically absorbent material. To avoid acoustic reflections at the surface of the backing block, the acoustic impedance of the backing block should be approximately matched to the acoustic impedance of the crystal, which is relatively high. The acoustic impedance of the backing block, Z, is the product of a speed of sound, c, and a density, ρ, for the backing block material:
Z=c·ρ

The density, ρ, can be increased by adding a high density material, such as tungsten powder to the backing block material, but this correspondingly also decreases the speed of sound in the material. Therefore, in two-layer piezoelectric assemblies, limitations are introduced when the acoustic impedance of the backing block is increased in the foregoing manner.

Thus, there is a need for an acoustic transducer not limited to two-layer crystal assemblies to improve the acoustic energy transmission.

### SUMMARY OF THE INVENTION

The preferred embodiment of the invention is a transducer device including a housing that encloses a three-layer piezoelectric crystal assembly in contact with a backing block to produce more finely resolved electric and acoustic pulses. In one aspect, a three-layer assembly includes a piezoelectric crystal flanked by a front and back matching layer with a backing block in contact with the back matching layer. In concert with the backing block, the front and back matching layers cooperatively interact to produce more highly resolved acoustic and electrical pulses than is achievable with transducers equipped with two-layer crystal assemblies. In another aspect, a transducer device has a housing that encloses a three-layer piezoelectric crystal assembly in contact with a backing block. The three-layer piezoelectric crystal assembly includes a piezoelectric crystal flanked by a front and a back matching layer. Along with the backing block in contact with the back matching layer, the combined interaction of the front and back matching layers of the preferred embodiment produces a more highly resolved acoustic pulse than is achievable with conventional two-layer piezoelectric crystal assemblies. Similarly, the three-layer piezoelectric crystal assembly transducer device cooperatively modifies the electrical signal of returning echoes to produce a more highly resolved electrical pulse than a comparable two-layer assembly.

The foregoing aspect thus maximizes the transmission of acoustic wave energy emanating from a transducer by coupling a three-layer piezoelectric assembly to the backing block. The compositions of the front and back matching layers are formulated to substantially match the impedance of the piezoelectric crystal. The interface location composition maximizes the transmitted wave energy by reducing the reflection from the backing block and results in the reduction of the pulse width of the transmitted wave by reducing waveform tailing to improve the axial resolution of the acoustic wave.

### BRIEF DESCRIPTION OF THE DRAWINGS

The preferred and alternative embodiments of the present invention are described in detail below with reference to the following drawings.

FIG. 1 is a schematic side view of a prior art acoustic transducer showing a two-layer piezoelectric crystal assembly;

FIG. 2 is a schematic side view of an acoustic transducer according to an embodiment of the invention having a three-layer piezoelectric crystal assembly;

FIG. 3A is a graph of the matching thickness of the back layer as a function of acoustic wavelength between 0 and 0.26λ and axial resolution at −6, −20, and −40 decibels;

FIG. 3B is a graph of the matching thickness of the back layer as a function of acoustic wavelength between 0.23 and 0.25λ and axial resolution at −6, −20, and −40 decibels;

FIG. 4A is a Hilbert waveform plot from an acoustic transducer with a front layer-piezoelectric crystal two-layer assembly at −20 decibels axial resolution; and

FIG. 4B is a Hilbert waveform plot from an acoustic transducer with a front layer-piezoelectric crystal-back three-layer assembly at −20 decibels axial resolution.

### DETAILED DESCRIPTION OF THE PREFERRED EMBODIMENT

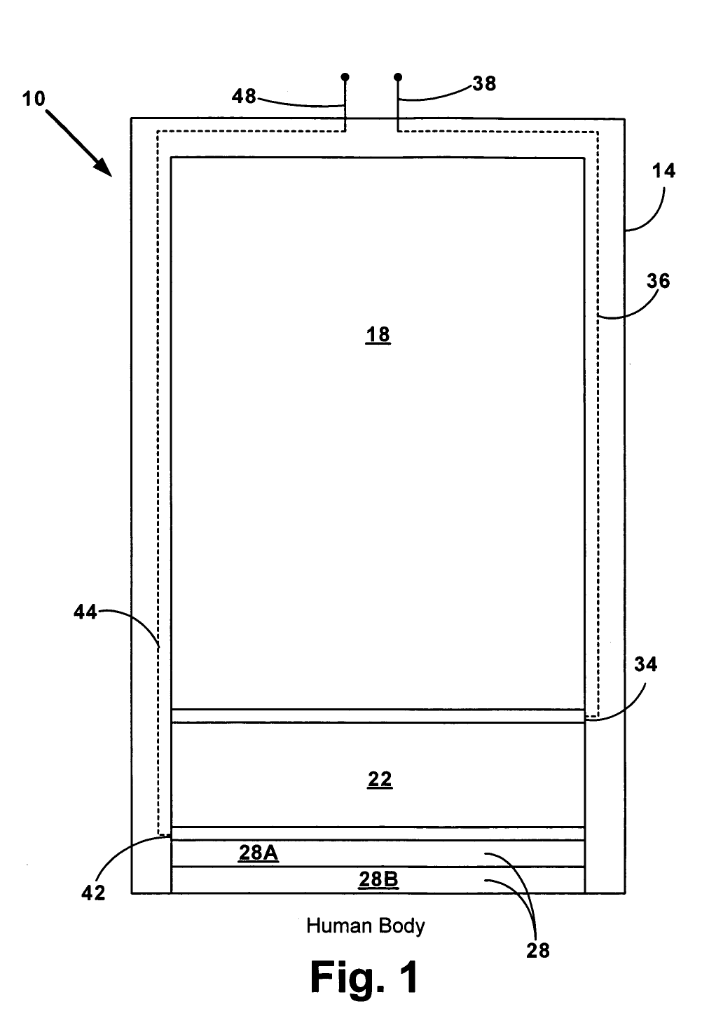

Wave reflection and transmission in multi-layered media governs the relationship between reflection/transmission coefficients and the thickness of middle (matching) layer of acoustic transducers. A design of an acoustic transducer having a two-layer piezoelectric crystal assembly in schematic side view is shown in FIG. 1. A transducer 10 is positioned in contact with a human body. The transducer 10 comprises a housing 14 encasing a backing block 18, a piezoelectric crystal 22, and a front matching layer 28. The piezoelectric crystal 22 and the front matching layer 28 define the two-layer piezoelectric crystal assembly. The front layer 28 includes a primary layer 28A adjacent to the crystal 22, and a secondary layer 28B proximal to the human body. Positioned above and in contact with the crystal 22 is a signal collector 34 connected with a signal lead 36 located in the housing 14. The signal lead 36 is in turn is in contact with a signal terminal 38 extending through the housing 14. Positioned beneath the crystal 22 is a ground contact 42 connected with a ground lead 44 located in the housing 14. The ground lead 44 is in turn is in contact with a ground terminal 48 extending through the housing 14.

The piezoelectric crystal 22 is stimulated to vibrate with a central frequency or wavelength upon receiving a stimulating or “on” voltage delivered from the signal terminal 38, through the signal lead 36, and to the signal collector 34. The thickness of the piezoelectric crystal 22 generally corresponds to a central frequency wavelength of the crystal 22. The crystal 22 stops vibrating when the stimulating signal is stopped, i.e., an “off” action, culminating in the release of an ultrasound pulse or bandwidth packet having a range of ultrasound frequencies distributed in a characteristic waveform approximately evenly about the central wavelength. Pulse echoes reflected back impinge upon the piezoelectric crystal 22 and cause it to vibrate and produce electrical signals that are delivered to the signal collector 34 for delivery to the signal terminal 38 via the signal lead 36.

Still referring to FIG. 1, the backing block 18 serves to dampen the vibrations of the piezoelectric crystal 22 between the “off” and “on” cycles of sequential pulses so that the bandwidth packet resolution is more pronounced or delineated with a minimum of waveform tailing. The backing block 18 is commonly made of tungsten powder distributed in an epoxy resin and liquid rubber to provide enough mass to mechanically dampen vibrations of the crystal 22 and to shorten the transmitted ultrasonic pulse. The tungsten powder and rubber composition of the block 18 is formulated to substantially match the acoustic impedance of the crystal 22 at the interface of the crystal 22 and the block 18 to minimize ultrasonic reflection. The block 18 also dampens “ringing” of the crystal 22 between reception of ultrasound pulse echoes, thereby lowering the noise, so that signals of returning echoes may be more easily and clearly detected and measured.

The front matching layer 28 is placed on the examination (or human body) side of the transducer 10 to improve the transmission of ultrasound into the body soft tissue. The thicknesses of the front matching layers, 28A and 28B, are commonly some fraction of the wavelength of the speed of sound within the layers 28A and 28B. For example, layers 28A and 28B are commonly configured to be ¼ the wavelength of their respective speed of sound associated with the central frequency wavelength of the pulse echo waveform traversing though the materials within the layers 28A and 28B. These ¼λ thicknesses of the proximal layer 28A and the secondary layer 28B cancel the small amount of ultrasound that is reflected from the distal and proximal surfaces of the front matching layer 28. The distance traveled between the surfaces is ½ wavelength and the waves are out of phase and thus cancelled. With this cancellation, the front matching layer 18 serves to increase the ultrasound energy into the body tissue and increases the bandwidth of the ultrasound pulse without any significant reflection. The improved or increase bandwidth similarly improves the axial resolution of the ultrasound pulse by decreasing the spatial pulse length.

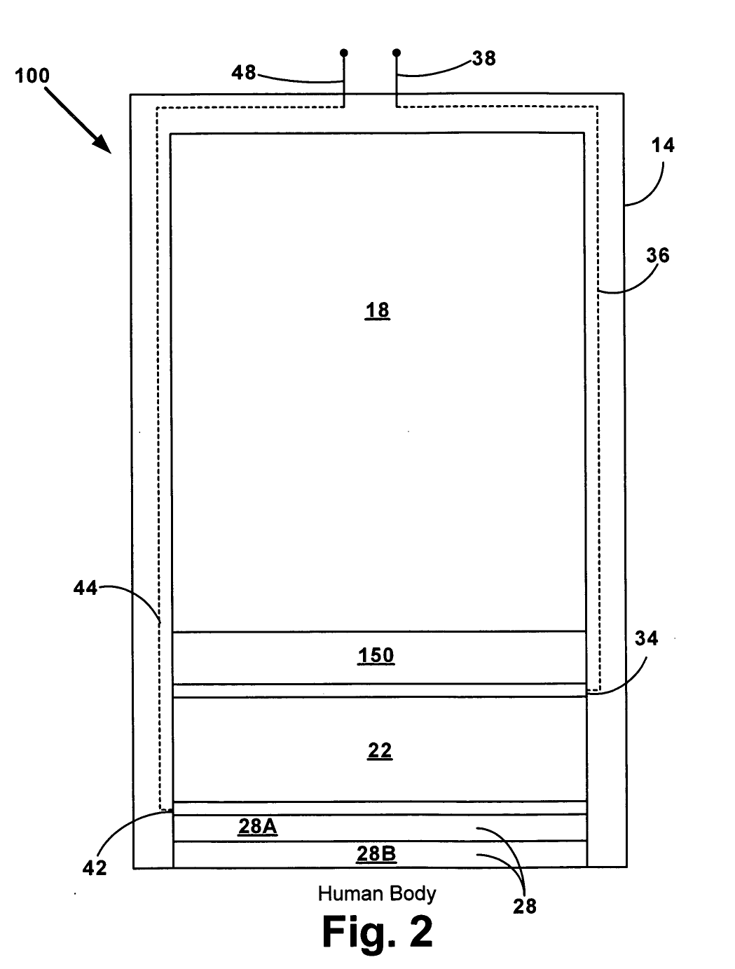

A preferred embodiment of the invention is shown in FIG. 2 that presents a schematic side view of an acoustic transducer of the instant invention having the three-layer piezoelectric crystal assembly. A transducer 100 is positioned over a human body. The transducer 100 comprises the housing 14 encasing the backing block 18, a back layer 150, the piezoelectric crystal 22, and the front matching layer 28. Positioned above and in contact with the crystal 22 is the signal collector 34 connected with the signal lead 36 located in the housing 14. The signal lead 36 is in turn is in contact with the signal terminal 38 extending through the housing 14. Positioned beneath the crystal 22 is the ground contact 42 connected with the ground lead 44 located in the housing 14. The ground lead 44 is in turn is in contact with the ground terminal 48 extending through the housing 14. Positioned next to the signal collector 34 is the back layer 150 that also is in contact with the crystal 22. The backing block 18 is in contact with the back layer 150.

The front layer 28, the piezoelectric crystal 22, and the back layer 150 define the three-layer piezoelectric crystal assembly 100. The front and back layers 28 and 150 are formulated to substantially match the acoustic impedance of the crystal 22. The front matching layer 28 is placed on the examination (or human body) side of the transducer 100. The three-layer assembly cooperatively interacts to improve the generation of more highly resolved acoustic pulses when the crystal 22 is stimulated with electrical pulses, and to generate more highly resolved electrical pulses when the crystal 22 receives an acoustic signal pulse. The thicknesses of the front matching layer 28A, 28B, and the back matching layer 150 are commonly ¼ the wavelength of the speed of sound within the layers 28A, 28B, and 150. This ¼ wavelength thickness serves to cancel the small amount of ultrasound that is reflected from the distal and proximal surfaces of the front matching layer 28 or the back matching layer 150. The distance traveled between the surfaces of the front and back matching layers 28 and 150 is ½ wavelength and the waves are out of phase and thus cancelled.

With this signal cancellation of acoustic reflections, the front matching layer 28 and the back matching layer 150 serve to increase the transmission of ultrasound energy pulses into the body tissue and the backing block without any significant reflection and decreases the spatial pulse length or signal bandwidth of the ultrasound or audible pulse. Thus, the efficiency of electro-to-mechanical conversion (as realized in acoustic pulse generation) is enhanced by the cooperative interaction of the three-layer piezoelectric crystal assembly that generates a shorter and more clearly defined acoustic pulse, either ultrasound or audible depending on the composition and configuration of the piezoelectric crystal 22.

Similarly, the efficiency of mechanical-to-electrical conversion (as realized in electric signal generation) is enhanced by the cooperative interaction of the three-layer piezoelectric crystal assembly that generates a shorter and more clearly defined electrical pulse caused by a returning acoustic echo, either ultrasound or audible depending on the composition and configuration of the piezoelectric crystal 22.

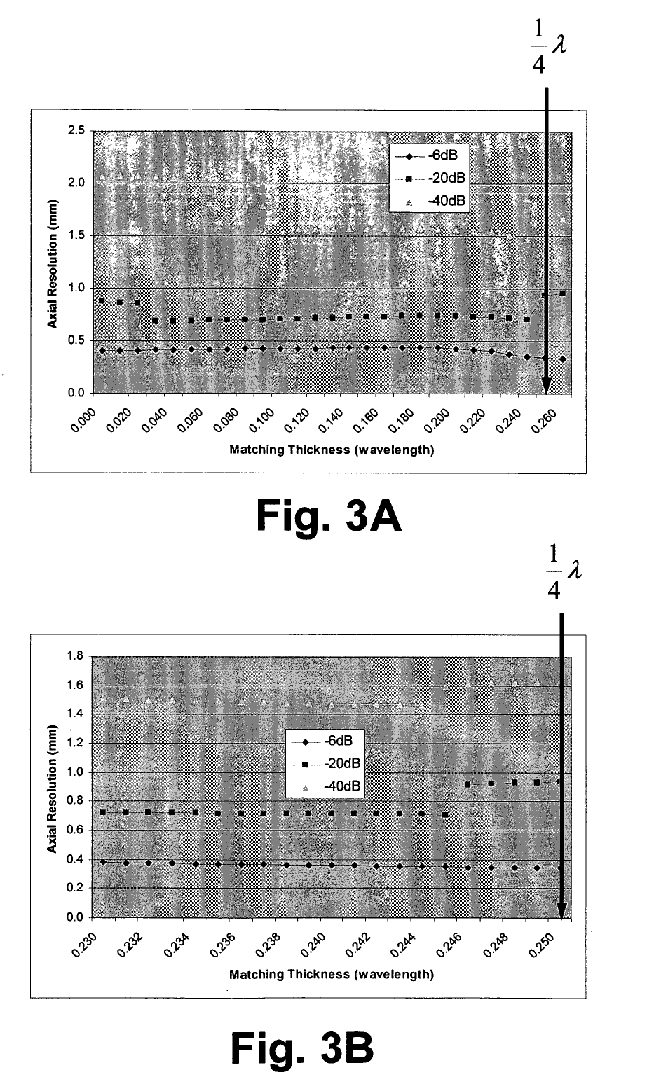

Axial resolution for a piezoelectric transducer is generally expressed in decibel levels of which −6, −20, and −40 dB levels are used for two-layer vs. three-layer analysis. FIG. 3 shows a plot of the matching thickness for the back layer 150 of the transducer assembly 100 of FIG. 2 as a function of acoustic wavelength and axial resolution at −6, −20, and −40 decibels obtained from the simulated values as discussed in the “Theory of Operation” below. Results show that the middle value at approximately 0.244λ represents a suitable matching layer thickness for axial resolution at −6, −20, and −40 decibels that is very close to the ¼λ value.

Theory of Operation

Wave reflection and transmission in three-layered media are presented, including the relationship between reflection/transmission coefficients and the thickness of middle (matching) piezoelectric crystal layer.

Reflection Coefficient on Multiple-Layer media

The reflection coefficient, R, from a three-layer medium is given by:

$$R = \frac{{Z}_{2} ( {Z}_{3} - {Z}_{1} ) cos ( {k}_{2} L ) + j ( {Z}_{2}^{2} - {Z}_{1} {Z}_{3} ) sin ( {k}_{2} L )}{{Z}_{2} ( {Z}_{3} - {Z}_{1} ) cos ( {k}_{2} L ) + j ( {Z}_{2}^{2} - {Z}_{1} {Z}_{3} ) sin ( {k}_{2} L )}$$

where, Z₁, Z₂, and Z₃ are the respective acoustic impedances of each of the three layers, k₂ is a wave constant and equal to 2π/λ₂ and λ₂ is the wavelength in the medium of the middle layer, and L is the width of the middle layer.

When the thickness of the middle layer, L, is one quarter wavelength, i.e.,

$$L = \frac{{λ}_{2}}{4} ,$$

the cosine and sine terms in the above equation become

$$\begin{matrix}{k}_{2} L = \frac{2 π}{{λ}_{2}} \cdot \frac{{λ}_{2}}{4} = \frac{π}{2} \\ cos ( {k}_{2} L ) = 0 \\ sin ( {k}_{2} L ) = 1\end{matrix}$$

Therefore the reflection coefficient, R, becomes:

$$R = \frac{{Z}_{2}^{2} - {Z}_{1} {Z}_{3}}{{Z}_{2}^{2} + {Z}_{1} {Z}_{3}}$$

If the numerator of R is set to zero, the reflection coefficient, R, will be zero, too. This means that if Z₂=\sqrt{Z₁Z₃}, and then there is no reflection from the three-layer medium (of course, in the case of continuous wave).

Transmission Coefficient in a Three-Layer medium.

If the ratio of reflection is R, then the transmission ratio, T, is,
T²=1−R²

In a three-layer medium, the reflection coefficient, R₁, and transmission coefficient, T₁, from a first boundary (between layer 1 and layer 2) is:

$${R}_{1} = \frac{{Z}_{2} - {Z}_{1}}{{Z}_{2} + {Z}_{1}} , {T}_{1} = 1 + {R}_{1}$$

And, for a second boundary (between layer 2 and layer 3):

$${R}_{2} = \frac{{Z}_{3} - {Z}_{2}}{{Z}_{3} + {Z}_{2}} , {T}_{2} = 1 + {R}_{2}$$

Therefore, the overall transmission coefficient, T, is given by:

$$T = {T}_{1} \cdot {T}_{2} = \frac{4 {Z}_{2} {Z}_{3}}{( {Z}_{2} + {Z}_{1} ) ( {Z}_{3} + {Z}_{2} )}$$

In order to determine a maximum value of the foregoing expression, a derivative of T with respect to Z₂ is set to zero:

$$\frac{ⅆ}{ⅆ {Z}_{2}} T = \frac{4 {Z}_{3} ( {Z}_{2} + {Z}_{1} ) ( {Z}_{3} + {Z}_{2} ) - 4 {Z}_{2} {Z}_{3} ( 2 {Z}_{2} + ( {Z}_{1} + {Z}_{3} ) )}{{( {Z}_{2} + {Z}_{1} )}^{2} {( {Z}_{3} + {Z}_{2} )}^{2}} = 0$$

The above equation can be reduced to: [symbol]
=4Z₃(Z₂+Z₁)(Z₃+Z₂)−4Z₂Z₃(2Z₂+(Z₁+Z₃))=0 [symbol]
=Z₃(−Z₂²+Z₁Z₃)=0

Therefore, when Z₂²=Z₁Z₃, the transmission coefficient, T, has its maximum value.

Simulation

The ideal matching layer has the quarter wavelength thickness and the impedance of \sqrt{Z₁Z₃}. The sound waves with different thicknesses of the backing matching layer are generated by version 3.02 PiezoCAD base obtained from Sonic Concepts on the following parameters (acoustic impedances). Impedance is expressed in Mrayls, where one Mrayl is defined as 1×10⁶ kg/[m²s].

Results for a preferred embodiment of the three-layer transducer 100 of FIG. 2 when excited at a frequency of 3.7 MHz and having a 0.4162 mm wavelength in water, when adjusted for differences in speed of sound between the piezoelectric crystal 22, the front matching layer 28 and back matching layer 150 are itemized below.

The front layer 28 comprises the primary layer 28A and secondary layer 28B, as shown in FIG. 2. The primary front matching layer 28A at approximately ¼λ: has an impedance of approximately 8.95 Mrayls (where the material is MF116 obtained from Emerson Cuming, Inc. of Randolph, Mass; or an equivalent) for the primary layer 28A at its speed of sound. The secondary front matching layer 28B=¼λ: or approximately 4.22 Mrayls (where the material is also MF110 obtained from Emerson Cuming, or an equivalent). Thickness is approximately 0.14 mm for the secondary layer 28B at its speed of sound.

The piezoelectric crystal 22 at approximately ½λ of the crystal 22 at its speed of sound: approximately 34.2 Mrayls (where the crystal material is EBL #3 obtained from Staveley Sensors, Inc., East Hartford, Conn.; or equivalent). The thickness is approximately 0.56 mm for the crystal 22 at its speed of sound.

The back matching layer 150 at approximately ¼λ. The backing layer 150 is formulated to be approximately 15.13 Mrayls with respect to the speed of sound in the layer 150. Thickness is approximately 0.16 mm for the backing layer 150 at its speed of sound.

The backing block 18 is approximately 6.69 Mrayls and approximately 8 mm in thickness. The materials of the backing block 18 are obtained from On-Hand Adhesives Inc., Mt. Prospect, Ill. (Epoxy and hardener), Noveon Inc., Cleveland, Ohio (liquid rubber), and Aldrich Chemical Company Inc., Milwaukee, Wis. (tungsten powder) or another equivalent suppliers.

The Hilbert envelopes of the two-layer transducer 10 of FIG. 1 and the three-layer transducer 100 of FIG. 2 were generated using Matlab to determine a spatial pulse length for the transducers 10 and 100. The processing includes calculating the spatial pulse length in microseconds (μsec or μs) at a −20 dB axial resolution limit line that intersects the Hilbert rectified waveform. PiezoCAD is also configured to calculate ranges of spatial pulse lengths, converted to mm, as a function of the thickness of the back layer 150 expressed in increments of the sound wavelength transmitting through the back layer 150 for axial resolution levels of −6 dB, −20 dB, and 40 dB.

The thickness of the back layer 150, expressed in fractional increments of the wavelength of the speed of sound traversing through the back layer 150, are plotted as shown in FIG. 3. A solid diamond symbol refers to the −6 dB axial resolution level, a solid square symbol refers to the −20 dB axial resolution level, and a solid triangle symbol refers to the −40 dB axial resolution level. FIG. 3 demonstrates the effectiveness of the three-layer transducer 100 in producing shorter spatial pulse lengths as a function of back layer 150 thickness, especially at −20 dB and −40 dB axial resolution levels.

The axial resolution plots in FIG. 3A demonstrate the simulated results of incrementally varying the thickness of the back matching layer 150 up to 0.260λ. The simulated results demonstrate for the −20 and −40 dB axial resolution levels, square cornered, step-like plateaus matching thickness values from 0 (or no back layer 150, i.e., equivalent to the two-layer transducer 10 configuration) to 0.260λ thickness for the back layer 150 (or three-layer transducer 100 configuration). FIG. 3B shows the detail plot between 0.23 and 0.25λ thickness. At 6 dB axial resolution, there is virtually no change between 0.230λ and 0.250λ. However, at the −20 and −40 axial resolution levels, the backing layer 150 provides improved axial resolution, so that a reduction in the spatial pulse lengths in a centralized region of the −20 and −40 dB plots is evident. The matching thickness value for the back layer 150 having the best axial resolution is 0.244λ that is substantially close to the theoretical 0.250λ (or ¼λ) value.

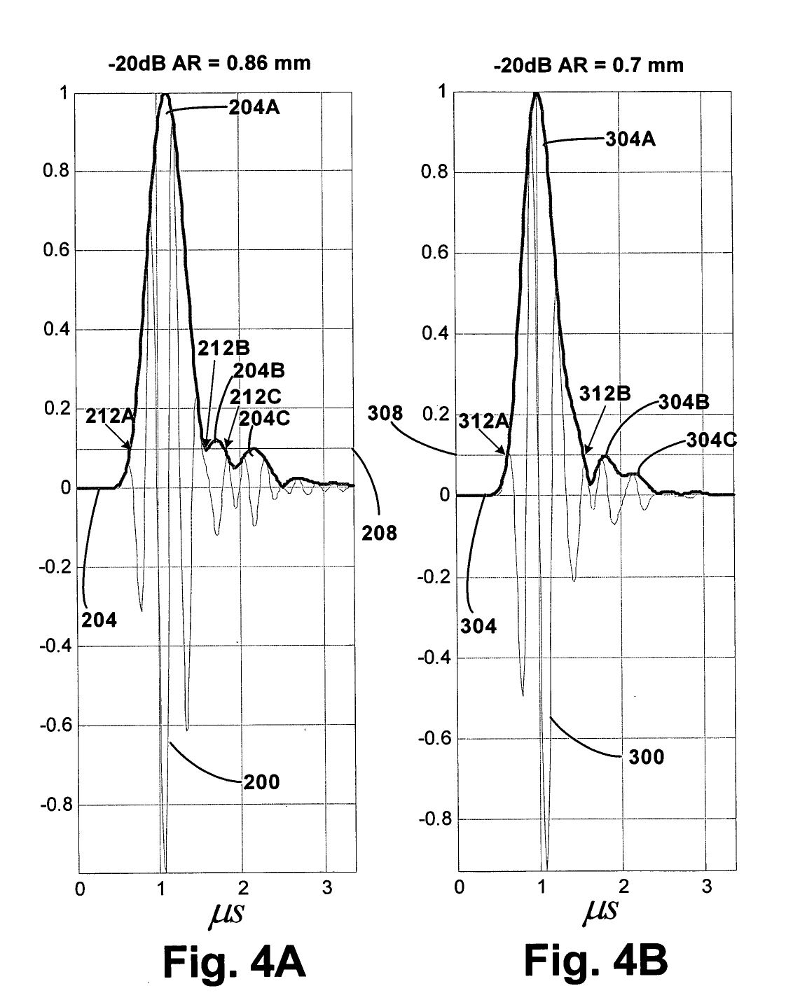

FIG. 4A is a Hilbert waveform plot (as normalized voltage y-axis vs. microseconds μs x-axis) from an acoustic transducer with a front layer-piezoelectric crystal two-layer transducer 10 assembly at −20 decibels axial resolution scanned at 0.77 mm per μs. The waveform plot includes a bimodal tracing 200; a rectified Hilbert envelope or tracing line 204 comprising a major peak 204A, a first minor peak 204B, and a second minor peak 204C; a −20 dB limit line 208 from the maxima of the major peak 204A, a lower limit 212A of approximately 0.7 μs, a first upper limit 212B of approximately 1.6 μs, and a second upper limit 212C of approximately 1.8 μs. The lower limit 212A and the first-second upper limits 212B-C are obtained from the intersection of the −20 dB limit line 208 along the Hilbert tracing line 204.

The spatial pulse time is defined as a “delta T” or time period obtained as a difference between the lower limit 212A and the greater or greatest upper limit whenever there is more than one upper limit. In FIG. 4A there are three upper limits, the greatest being the second upper limit 212C obtained by the intersection of the −20 dB limit line 208 with the Hilbert tracing line 204. The spatial pulse time for the two-layer transducer 10 illustrated in FIG. 4A is the absolute difference between the second upper time limit 212C and the lower limit 212A, or 1.8 μs-0.7 μs, equivalent to a spatial pulse time of 1.1 μs. With a scan rate of 0.77 mm/μs, the 1.1 μs space pulse time renders an axial resolution of the acoustic pulse emanating from this two-layer piezoelectric transducer 10 equivalent to a spatial pulse length of 0.86 mm.

FIG. 4B is a Hilbert waveform plot (as normalized voltage y-axis vs. microseconds μs x-axis) from a three-layer acoustic transducer 100 configured with the back matching layer 150 at −20 decibels axial resolution scanned at 0.77 mm per μs. The waveform plot includes a bimodal tracing 300; a rectified Hilbert tracing 304 comprising a major peak 304A, a first minor peak 304B, and a second minor peak 304C; a −20 dB limit line 308 from the maxima of the major peak 304A, a lower limit 312A of approximately 0.64 μs and an upper limit 312B of approximately 1.55 μs. The lower limit 312A and the upper limit 312B are obtained by the intersection of the limit line 308 with the Hilbert tracing line 304.

The spatial pulse time period is defined as a “delta T” or time period obtained as a difference between the lower limit 312A and the greater or greatest upper limit whenever there is more than one upper limit. In FIG. 4B there is only one upper limit, namely the upper limit 312B. The spatial pulse time for the three-layer transducer 100 illustrated in FIG. 4B is the absolute difference between the upper time limit 312B and the lower limit 312A, or 1.55 μs-0.64 μs, equivalent to a spatial pulse time of 0.91 μs. With a scan rate of 0.77 mm/μs, the 0.91 μs space pulse time renders an axial resolution of the acoustic pulse emanating from this three-layer piezoelectric transducer 100 equivalent to a spatial pulse length of 0.70 mm.

The three-layer transducer 100 having the back matching layer 150 improves the axial resolution by shortening the spatial pulse length. The axial resolution for the two-layer transducer 10 is 0.86 mm and for the three-layer transducer 100 is 0.70 mm. Thus, the spatial pulse length is shortened by 0.16 mm for the three-layer transducer 100. Thus, the three-layer transducer 100 having the back matching layer 150 improves the axial resolution by approximately 23%.

The three-layer transducer 100 advantageously exhibits substantially lower energy losses due to reduction or elimination of interface reflections and improved non-signal vibration damping.

Accordingly, the scope of the invention is not limited by the disclosure of the preferred embodiment. Instead, the invention should be determined entirely by reference to the claims that follow.

APPENDIX

Matlab Source Code:

clear all
c = 1540;
directory = ‘e:\work\data\ts0000\PiezoCAD\’;
figure(1), clf
for ii = 1 : 8,

switch ii

case 1

filename = ‘Front0_Back0’;

case 2

filename = ‘Front2_Back0’;

case 3

filename = ‘Front0_Back1’;

case 4

filename = ‘Front2_Back1’;

case 5

filename = ‘Front2_BackPerfect’;

case 6

filename = ‘Front0_BackPerfect’;

case 7

filename = ‘FrontPerfect_BackPerfect’;

case 8

filename = ‘Front2_Back2’;

otherwise

end

fid = fopen([directory, filename, ‘.dat’], ‘rt’);
while feof(fid) == 0

if findstr(fgetl(fid), “‘usec’),

cnt = 1;
while feof(fid) == 0

temp = fgetl(fid);
I = findstr(temp, “”);
beam(cnt,1) = str2num(temp(I(1)+1:I(2)−1));
beam(cnt,2) = str2num(temp(I(3)+1:I(4)−1));
cnt = cnt + 1;

end

end

end
fclose(fid);
beam = beam(1:round(length(beam)/4),:);
Ts = beam(2,1) * 1e−6;
Fs = 1/Ts;
% Axial resolution
H = abs(hilbert(beam(:,2)));
Y = max(H);
threshold = 10\hat{ }(−20/20) * Y;
I = find(H >= threshold);
AR = I(end)−I(1);
subplot(2,4,ii),

plot(beam(:,1), beam(:,2)), hold on,
plot(beam(:,1), H, ‘g−’, ‘linewidth’, 2),
plot(beam(:,1), ones(length(beam),1) * threshold, ‘r’), hold on,
axis tight, grid on
I = findstr(filename, ‘_’);
title([filename(1:I−1), ‘ ’, filename(I+1:end), ‘, ’,
num2str(round(AR*c/Fs/2 *

1e3 * 1e2)/1e2), ‘ mm’])

end

The embodiments of the invention in which an exclusive property or privilege is claimed are defined as follows:

1. A transducer device comprising:
a piezoelectric crystal having a first side and an opposing second side, the crystal further configured to generate and receive electrical pulses and to generate and receive acoustic pulses;
a front matching layer in contact with the first side, the front layer being matched to the impedance of the crystal;
a back matching layer in contact with the second side, the back layer being matched to the impedance of the crystal; and
a backing block in contact with the back matching layer,
wherein at least one of the duration and shape of the waveform of the acoustic pulses emanating from the front layer are modified by the front and back matching layers.

2. The device of claim 1, wherein the piezoelectric crystal is operable to generate and receive acoustic pulses at ultrasonic frequencies.

3. The device of claim 2, wherein the axial resolution of the waveform is shortened by a selected combination of the front and back layers than by the front layer.

4. The device of claim 2, wherein the axial resolution of the waveform is shortened by a selected combination of the front and back layers than by the back layer.

5. The device of claim 1, wherein the thickness of the piezoelectric crystal is approximately one-half of a wavelength of the acoustic pulse traversing the crystal.

6. The device of claim 1, wherein the thickness of the front layer is approximately one-half of a wavelength of the acoustic pulse traversing the front layer.

7. The device of claim 6, wherein the front layer further comprises a primary layer of approximately one-fourth of a wavelength of the acoustic pulse and an abutting secondary layer of approximately one-fourth of a the wavelength of the acoustic pulse.

8. The device of claim 1, wherein a thickness of the back matching layer is approximately one-fourth of the wavelength of the acoustic pulse traversing the back matching layer.

9. A transducer device comprising:
a piezoelectric crystal having a first side and an opposing second side, the crystal being further configured to generate and receive electrical pulses and to generate and receive acoustic pulses;
a front matching layer in contact with the first side, the front layer being matched to the impedance of the crystal and configured to transmit acoustic pulses from and to the crystal;
a back matching layer in contact with the second side, the back layer being matched to an impedance of the crystal; and
a backing block in contact with the back matching layer,
wherein at least one of a duration and shape of a waveform of the acoustic pulses emanating from the front layer are modified by the front and back matching layers, and the electrical signal produced by the crystal upon receipt of an acoustic signal transmitted by the front layer is modified by the front and back matching layers.

10. The device of claim 9, wherein the piezoelectric crystal is responsive to an acoustic pulse at an ultrasonic frequency.

11. The device of claim 10, wherein the axial resolution of the waveform is shortened by a selected combination of the front and back layers than by the front layer.

12. The device of claim 10, wherein the axial resolution of the waveform is shortened by a selected combination of the front and back layers than by the back layer.

13. A method to manufacture a transducer device comprising:
forming a piezoelectric crystal to generate and receive electrical pulses and to generate and receive acoustic pulses, the crystal having a first side and an opposing second side;
applying a front matching layer in contact with the first side, the front layer being matched to the impedance of the crystal;
applying a back matching layer in contact with the second side, the back layer being matched to the impedance of the crystal; and
applying a backing block in contact with the back matching layer,
wherein at least one of the duration and shape of the waveform of the acoustic pulses emanating from the front layer are modified by the front and back matching layers.

14. The method of claim 13, wherein the thickness of the piezoelectric crystal is approximately half the central wavelength of the acoustic pulse waveform.

15. The method of claim 14, wherein the piezoelectric crystal is operable to generate and receive acoustic pulses at ultrasonic frequencies.

16. The method of claim 13, wherein the axial resolution of the waveform is shortened by a selected combination of the front and back layers than by the front layer.

17. The method of claim 13, wherein the axial resolution of the waveform is shortened by a selected combination of the front and back layers than by the back layer.

18. The method of claim 13, wherein the thickness of the front layer is approximately one-half of the wavelength of the acoustic pulse traversing the front layer.

19. The method of claim 18, wherein the front layer further comprises a primary layer adjacent to the crystal and a secondary layer adjacent to the exit side of the transducer.

20. The method of claim 13, wherein the crystal, the front layer, the back layer, and the backing block are encased in a housing configured to send and receive electrical signals to and from the crystal.
